(19) United States
(12) Patent Application Publication
(10) Pub. No.: US 2002/0023715 A1
(43) Pub. Date: Feb. 28, 2002

(54) Substrate polishing apparatus and substrate polishing mehod

(76) Inventors: Norio Kimura, Kanagawa (JP); Tatsuya Kohama, Kanagawa (JP); Makoto Akagi, Kanagawa (JP)

Correspondence Address: WENDEROTH, LIND & PONACK, L.L.P., 2033 K STREET N. W., SUITE 800, WASHINGTON, DC, 20006-1021, US

(21) Appl. No.: 09/864,208

(22) Filed: May 25, 2001

(30) Foreign Application Priority Data
May 26, 2000 (JP) 157007/2000
Oct. 11, 2000 (JP) 310454/2000

(51) Int. Cl. H01L 21/304

(52) U.S. Cl. 156/345

(57) ABSTRACT

A substrate polishing apparatus wherein semiconductor substrate is held by a top ring 10-2 or 11-2 and is pressed against a polishing surface of a polishing table 10-1 or 10-2. A surface to be polished of the semiconductor substrate is polished by a relative movement between the semiconductor substrate and the polishing surface. The apparatus includes pressing force changing mechanism for changing an pressing force for pressing the semiconductor substrate, relative movement seed changing mechanism for changing the number of revolutions of the top ring and/or the polishing table, and control mechanism. The control mechanism performs the polishing through plural polishing processes on the polishing table 10-1 or 10-2 while changing the pressing force and the number of revolutions.

### BACKGROUND OF THE INVENTION

The present invention relates to a substrate polishing apparatus and a substrate polishing method for polishing a metallic coating or film formed on a surface of a substrate used in a semiconductor device manufacturing process, and, particularly in a process for forming metallic wiring with copper and the like. Further, the present invention relates to a substrate polishing method for flattening and mirror-polishing a film formed on a surface of a semiconductor substrate, and more particularly it relates to a substrate polishing method suitable for flattening and mirror-polishing a metallic film formed on the surface of the substrate.

As integrating density on a semiconductor device has been increased, adoption of material of higher conductivity has been requested as material for forming a wiring circuit. To satisfy such request, a polishing method in which a film having high conductivity and made of copper or alloy thereof is formed on a surface of a substrate having grooves and/or holes corresponding to a wiring pattern and the substrate surface is polished by a polishing apparatus with chemical and mechanical polishing (CMP) in such a manner that the film is removed from the substrate surface while remaining the film material filling the grooves and/or holes corresponding to the wiring pattern has been brought into notice.

As shown in FIG. 1(a), in a semiconductor substrate W, an insulation film 102 made of SiO₂ is deposited on a conductive layer 101a formed on a semiconductor substrate 101 on which a semiconductor elements are formed, and contact holes 103 and wiring grooves 104 are formed in the film by a lithography etching technique, and a barrier layer 105 made of TiN is coated on the film and a feed seed layer 107 for electroplating is formed on the barrier layer.

Then, as shown in FIG. 1(b), by applying copper (Cu) plating on the surface of the semiconductor substrate W, the contact holes 103 and the grooves 104 of the semiconductor substrate 101 are filled with copper, and a copper plating layer 106 is deposited on the insulation film 102. Thereafter, by chemical and mechanical polishing, the copper plating layer 106 on the insulation film 102 is removed so that the surface of the copper plating layer 106 filled in the contact holes 103 and the wiring grooves 104 becomes substantially flush with the surface of the insulation film 102. As a result, the wiring comprised of the copper plating layer 106 as shown in FIG. 1(c) is obtained.

When the barrier layer 105, feed seed layer 107 and copper plating layer 106 as plural kinds of layers formed on the insulation film 102 are polished by the chemical and mechanical polishing, the polishing must be performed while changing polishing condition at two or three stages. And, in each stage polishing, since a polishing table must be changed, as a whole, the number of tables is increased and the entire polishing apparatus is made bulky and complicated and is also made more expensive. Further, through-put of the semiconductor substrate polishing cannot be improved.

Further, in recent years, as integrating density on a semiconductor device has been increased, circuit wiring has been made finer and a distance between the wirings has been shortened. Particularly, in case of optical lithography handling line width of 0.5 μm or less, since focal depth becomes small, flatness of a focusing plane of a stepper must be enhanced. To this end, a surface of a semiconductor wafer must be flattened. As one of such flattening methods, polishing by means of a polishing apparatus is adopted.

In the past, such a polishing apparatus includes a turn table on which a polishing cloth is adhered or a turn table constituted by grinding stone having an upper polishing surface, and a top ring, which turn table and top ring are rotated independently with independent number of revolutions, so that the top ring applies predetermined pressure onto the turn table, thereby flattening and mirror-polishing a surface of an object to be polished (polished object) interposed between the turn table and the top ring.

FIG. 1(d) is a cross-sectional view of a substrate as an object to be polished. As shown, in the substrate, grooves or holes 305 are formed in an upper surface of an oxidation film 301 such as a SiO₂ film formed on an upper surface of a silicon substrate (not shown), and a titanium (Ti) film 302 and a titanium nitride (TiN) film 303 are successively formed on the surface (including inner surfaces of the grooves or holes 305) of the oxidation film 301, and a tungsten (W) film 304 is formed on the TiN film to fill the grooves or holes 305.

In the past, in order to polish the substrate having the above-mentioned cross-section, the substrate was polished by a single polishing process without changing a substrate pressing load for pressing the substrate against the polishing surface of the polishing table, the number of revolutions of the polishing table and the top ring and slurry. For example, after slurry polishing was effected by using slurry as polishing liquid with substrate pressing load of 500 kgf/cm², water polishing was effected with substrate pressing load of 50 kgf/cm². If the formed surface of the tungsten film 304 of the substrate is polished by such polishing processes until the titanium (Ti) film 302 is removed, as shown in FIG. 1(e), the oxidation film 301 will subjected to erosion, i.e., oxide erosion, which leads in unevenness polished surface, thereby preventing uniform or flat polishing.

### SUMMARY OF THE INVENTION

The present invention is made in consideration of the above-mentioned conventional drawbacks, and an object of the present invention is to provide a substrate polishing apparatus and a substrate polishing method, in which, when plural kinds of films on a semiconductor substrate are polished, plural stage polishing processes can be performed on a single polishing table to reduce the number of tables and to make the entire apparatus compact and which can enhance through-put of semiconductor substrate polishing.

Another object of the present invention is to a substrate polishing method suitable for flattening uniformly and for mirror-polishing a surface to be polished, by polishing films formed on a substrate surface, particularly plural different metallic films successively formed on the substrate surface.

To achieve the above objects, according to a first aspect of the present invention, there is provided a substrate polishing apparatus comprising a polishing table having a polishing surface and a top ring for holding a substrate, and wherein the semiconductor substrate held by the top ring is pressed against the polishing surface of the polishing table and a surface to be polished of the semiconductor substrate is polished by a relative movement between the semiconductor substrate and the polishing surface, and characterized in that it further comprises pressing force changing mechanism for changing an pressing force for pressing the semiconductor substrate, relative movement changing mechanism for changing the speed of relative movement of the top ring and/or the polishing table, and control mechanism and that the control mechanism performs plural polishing processes on the same polishing table while changing the pressing force and the number of revolutions through the pressing force changing mechanism and the revolution number changing mechanism.

According to another aspect of the present invention, in the above-mentioned substrate polishing apparatus, there is further provided film thickness detecting means for detecting a film thickness of the semiconductor substrate, and the control mechanism performs transfer from the preceding polishing process to the next polishing process on the basis of a film thickness detection signal detected by the film thickness detecting means.

According to a further aspect of the present invention, in the above-mentioned substrate polishing apparatus, there is further provided dressing means for dressing the polishing surface of the polishing table or cleaning mechanism for cleaning the polishing surface of the polishing table, and the control mechanism controls the dressing mechanism or the cleaning mechanism between the polishing processes to effect the dressing or the cleaning of the polishing surface of the polishing table.

According to a still further aspect of the present invention, there is provided a substrate polishing method in which a semiconductor substrate held by a top ring is urged against a polishing surface of a polishing table and a surface to be polished of the semiconductor substrate is polished by a relative movement between the semiconductor substrate and the polishing surface, and characterized in that the semiconductor substrate is polished on the same polishing table through plural polishing processes while changing an pressing force for pressing the semiconductor substrate and the number of revolutions of the top ring and/or the polishing table.

A purpose for polishing the semiconductor substrate on which a pattern was formed is to remove minute unevenness (for example, unevenness having width of 0.1 μm to 2 μm and height of 500 nm to 1000 nm) and to achieve flatness. However, since a polishing pad has elasticity, the pad follows certain unevenness, with the result that the unevenness cannot be removed completely. In this case, the flatness is apt to be achieved if the polishing is performed with small load (urging force) and faster rotational speed. However, since the load is small, a polishing speed is reduced. In consideration of this, as mentioned above, by performing the polishing on the same polishing table through the plural polishing processes while changing the pressing force for pressing the semiconductor substrate and the number of revolutions of the top ring and/or the polishing table, the polishing is firstly effected with great load and fast rotational speed, and, thereafter, the unevenness is removed with small load. In this way, the polishing for flattening the surface to be polished can be achieved. Further, by reducing a relative speed for finish polishing, removal of scratches on the surface can be facilitated.

According to a further aspect of the present invention, in the above-mentioned substrate polishing method, when the plural polishing processes are performed, the polishing is effected while adding polishing liquid and/or reagent liquid having pH at the same side as pH 7.

According to a still further aspect of the present invention, in the above-mentioned substrate polishing method, when the plural polishing processes are performed, the polishing is effected by using same abrasive grain.

According to a further aspect of the present invention, there is provided a substrate polishing method in which a semiconductor substrate held by a top ring is urged against a polishing surface of a polishing table and a surface to be polished of the semiconductor substrate is polished by a relative movement between the semiconductor substrate and the polishing surface, and characterized in that the polishing is effected on the single polishing table through plural stage polishing processes, and, after one stage polishing process is finished, the polishing surface of the polishing table is cleaned, and then the next stage polishing process is performed.

To achieve the above object, according to a further aspect of the present invention, there is provided a substrate polishing method in which a substrate held by a top ring is urged against a polishing surface of a polishing table and a film formed on a surface of the semiconductor substrate is polished to achieve flatness by a relative movement between the semiconductor substrate and the polishing surface, and characterized in that the polishing is performed through three or more polishing processes in which at least one of a substrate pressing load for pressing the substrate against the polishing surface of the polishing table, a relative speed between the polishing table and the substrate and polishing liquid is changed.

As mentioned above, by performing the polishing through three or more polishing processes in which at least one of the substrate pressing load, the relative speed between the polishing table and the substrate and the polishing liquid is changed (for example, the substrate pressing load is changed), uniformity of the polished surface is improved in comparison with the prior art, which will be described later.

According to a still further aspect of the present invention, in the above-mentioned substrate polishing method, completion of at least last polishing process among three or more polishing processes is determined by detection of a thickness of the film.

As mentioned above, by determining the completion of the polishing process on the basis of the detection of the thickness of the film, for example, when the polishing of a certain kind of film is finished and the transfer to the polishing for another kind of film is effected, a polishing condition (for example, polishing liquid and substrate pressing load) can be changed to suite for such kind of film.

According to a further aspect of the present invention, in the above-mentioned substrate polishing method, after at least last polishing process among three or more polishing processes is finished, a water polishing process using water as the polishing liquid is performed.

According to a still further aspect of the present invention, in the above-mentioned substrate polishing method, an atomizer polishing process using mixture of water and inert gas as the polishing liquid is added to the water polishing process.

As mentioned above, by performing the water polishing process and the atomizer polishing process after the last polishing process is finished, since high temperature portions of the surface to be polished of the substrate and the polishing surface of the polishing table heated during the preceding polishing process are cooled and the polishing liquid (for example, slurry) used in the preceding polishing process is removed, erosion of the surface to be polished of the substrate can be prevented, thereby enhancing uniformity.

According to the other aspect of the present invention, in the above-mentioned substrate polishing method, the films formed on the substrate surface may be an oxidation film, a Ti film, a TiN film and a W film successively laminated on the substrate surface.

As mentioned above, by polishing the substrate on which the W film was formed through three or more polishing processes while changing the substrate pressing load for example, uniformity of the surface to be polished of the substrate will be improved in comparison with the prior art, as will be described later.

### BRIEF DESCRIPTION OF THE DRAWINGS

FIGS. 1(a) to 1(c) are explanatory views for forming a circuit wiring on a semiconductor substrate, FIG. 1(d) is a sectional view of a substrate to be polished, and FIG. 1(e) is a sectional view of a substrate polished by a conventional substrate polishing method;

FIG. 2 is a plan view showing a substrate processing apparatus having a substrate polishing apparatus according to the present invention;

FIG. 3 is a view showing a construction of a polishing device of the substrate polishing apparatus according to the present invention;

FIG. 4 is a view showing a construction of a cleaning mechanism for a polishing surface of a polishing table of the substrate polishing apparatus according to the present invention;

FIG. 5 is a view showing a construction of a cleaning mechanism for a polishing surface of a polishing table of the substrate polishing apparatus according to the present invention;

FIG. 6 is a view showing a construction of a first cleaning machine of the substrate polishing apparatus according to the present invention;

FIG. 7 is a perspective view of a second robot of the substrate polishing apparatus according to the present invention;

FIG. 8 is a view showing a construction of a film thickness measuring device for measuring a film thickness the substrate during the polishing used by the substrate polishing apparatus according to the present invention;

FIG. 9 is a schematic view showing a substrate polishing apparatus carrying out a substrate polishing method according to the present invention;

### DETAILED DESCRIPTION OF THE INVENTION

Table 1 is a table showing an example of a relationship between a flow of polishing processes of the polishing apparatus according to the present invention and kind of abrasive grain/slurry, top ring pressing force and top ring revolution number used;

Table 2 is a table showing a relationship between polishing processes of the substrate polishing method according to the present invention and polishing conditions;

Table 3 is a table showing an example of uniformity in substrate polishing effected by a conventional substrate polishing method; and

Table 4 is a table showing an example of uniformity in substrate polishing effected by the substrate polishing method according to the present invention.

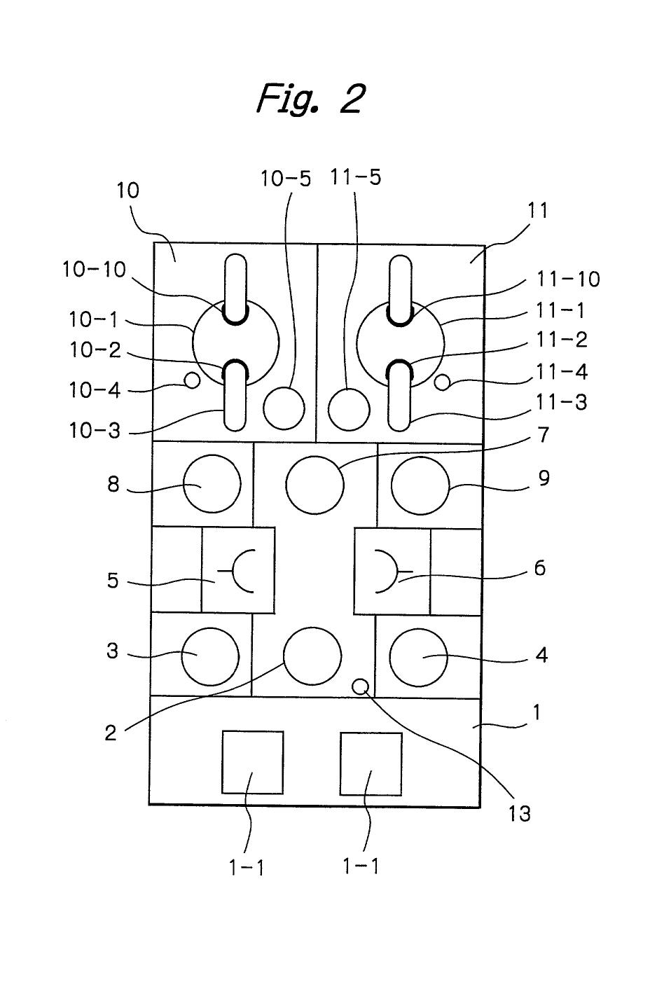

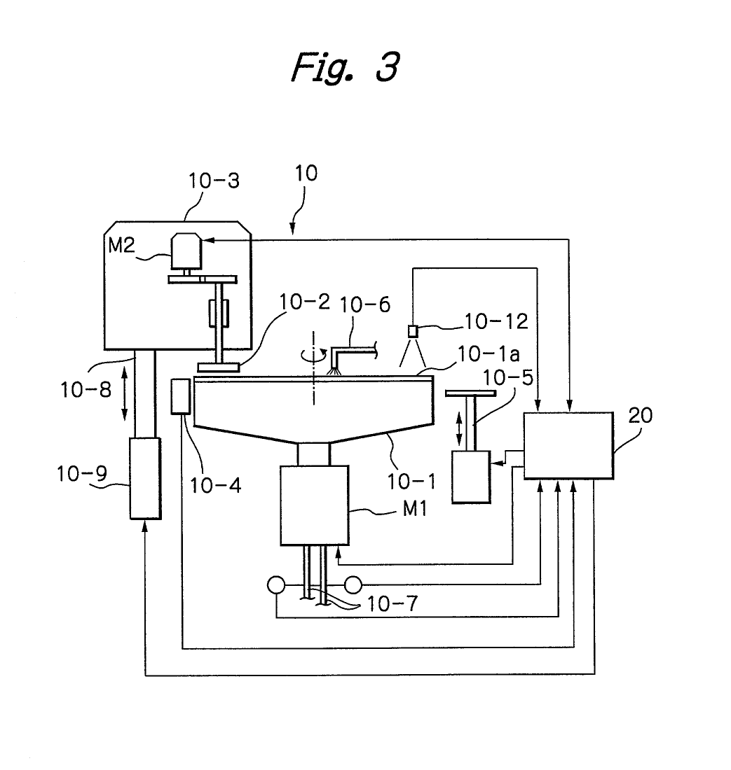

The present invention will now be explained in connection with embodiments thereof with reference to the accompanying drawings. FIG. 2 is a plan view showing a substrate processing apparatus having a substrate polishing apparatus according to the present invention. The substrate polishing apparatus includes a load/unload portion 1, a first robot 2, second cleaning machines 3, 4, a reverse rotation machine 5, a reverse rotation machine 6, a second robot 7, first cleaning machines 8, 9, a first polishing device 10 and a second polishing device 11.

The polishing device 10 includes a polishing table 10-1, a top ring 10-2, a top ring head 10-3, a film thickness measuring device 10-4, a pusher 10-5 and a dresser 10-10. Further, the polishing device 11 includes a polishing table 11-1, a top ring 11-2, a top ring head 11-3, a film thickness measuring device 11-4, a pusher 11-5 and a dresser 11-10.

Further, a drying condition film thickness measuring device 13 for measuring a film thickness in a drying condition after polishing is disposed in the vicinity of the first robot 12.

In the substrate processing apparatus having the above-mentioned arrangement, a semiconductor substrate W on which a feed seed layer 107 and a plating film layer 106 were formed is set in a cassette 1-1 to rest it on a load port of the load/unload portion 1. The semiconductor substrate W is picked up from the cassette by the first robot 2, and the substrate is transferred to the reverse rotation machine 5 or the reverse rotation machine 6. In this case, the surface of the semiconductor substrate W on which the plating film layer 106 was formed is directed upwardly, and the surface on which the plating film layer 106 was formed is turned over by the reverse rotation machine 5 or the reverse rotation machine 6 to be directed downwardly.

The semiconductor substrate W turned over by the reverse rotation machine 5 or the reverse rotation machine 6 is picked up by the second robot 7, and the semiconductor substrate W is rested on the pusher 10-5 of the polishing device 10 or the pusher 11-5 of the polishing device 11. The semiconductor substrate W is absorbed by the top ring 10-2 or the top ring 11-2, and a surface to be polished of the semiconductor substrate W is urged against a polishing surface of the polishing table 10-1 or the polishing table 11-1, and then the polishing is effected.

FIG. 3 is a view showing a schematic construction of the polishing device 10 according to the present invention. As shown, the polishing device 10 has the polishing table 10-1 rotated by a motor M1 and the top ring 10-2 rotated by a motor M2, and the polishing table 10-1 and the top ring 10-2 is designed so that the numbers of revolutions thereof can be changed by a control portion 20. Further, the top ring head 10-3 can be turned around a rotary shaft 10-8 to be positioned above the polishing table 10-1 or above the film thickness measuring device 10-4 or above the pusher 10-5.

The polishing surface 10-1a of the polishing table 10-1 is constituted by foam polyurethane or material in which abrasive grain is secured or impregnated. As abrasive grain of grinding or abrasive liquid supplied from a polishing liquid supply nozzle 10-6, silica is used, and, as oxidizing agent, material capable of oxidizing copper (Cu) such as hydrogen peroxide water or ammonia is used. The polishing table 10-1 and slurry or dressing water are temperature-adjusted to keep chemical reaction speed constant. In particular, the polishing table 10-1 is formed from alumina or ceramic such as SiC having good heat transferring ability, and a temperature-adjustment water pipe 10-7 is provided to supply temperature-adjustment water in the interior of the table.

The top ring head 10-3 can be shifted upwardly and downwardly by a vertical direction driving mechanism 10-9, so that the semiconductor substrate W held by the top ring 10-2 can be urged against the polishing table with any pressing force by changing the pressing force under the control of the control portion 20. Further, as the film thickness measuring device 10-4 used for detecting an end point of the film thickness, an eddy current type or an optical type which will be described later is used to effect film thickness measurement of the copper plating film layer 106 and the copper feed seed layer 107 or detection of a film surface of a barrier layer 105 and an insulation film 102, and detection output is transferred to the control portion 20. Further, a surface temperature of the polishing surface 10-1a is detected by a radiation thermometer 10-12, and detection output is transferred to the control portion 20. Incidentally, since the construction of the polishing device 11 is the same as the polishing device 10, explanation thereof will be omitted.

The polishing is effected through plural polishing processes. In a first polishing process, the copper plating film layer 106 is polished. A main purpose of the polishing in the first polishing process is to remove stepped difference, i.e., unevenness, and, in this case, slurry having good unevenness removing ability is used. For example, slurry capable of reducing initial unevenness of 700 nm of the copper plating film layer 106 having a film thickness of about 100 μm to 20 nm or less is used. In this case, the control portion 20 utilizes a polishing condition improving the unevenness removing ability by reducing the load for pressing the semiconductor substrate W against the polishing surface 10-1a of the polishing table 10-1 in a second polishing process to half or less of the pressing force in the first polishing process. The control of the load is effected by controlling the vertical direction driving mechanism 10-9 by means of the control portion 20.

As the film thickness measuring device 10-4 for detecting end point of the film thickness in the second polishing process, when the copper plating film layer 106 is remained to a thickness of 500 nm or more, a film thickness measuring device of eddy current type is used, and, when the layer 106 is remained to a thickness smaller than 500 nm or when the layer is removed until the surface of the barrier layer 105 is exposed, a film thickness measuring device of optical type is used.

Although the barrier layer 105 is polished after the polishing of the copper plating film layer 106 was finished, if the barrier layer 105 cannot abraded by the initially used slurry, composition of the slurry must be changed. Thus, the slurry used in the first and second polishing processes and remaining on the polished surface upon completion of the second polishing process is cleaned and removed by water polishing or water jet or atomizer or dresser, and then, the third polishing process is started.

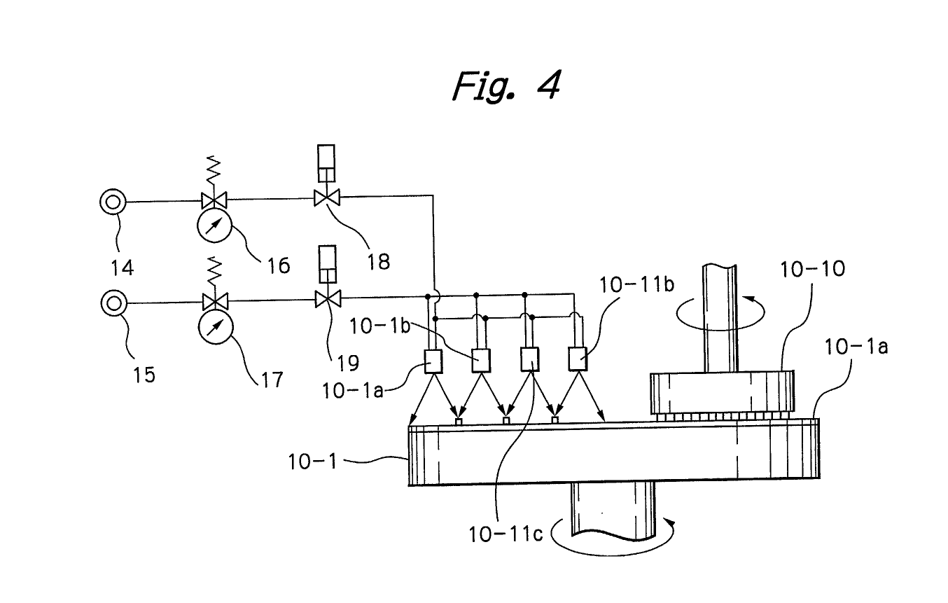

FIG. 4 is a view showing a cleaning mechanism for cleaning the polishing surface 10-1a of the polishing table 10-1. As shown, a plurality (four in the illustrated embodiment) of mixing and injecting nozzles (atomizers) 10-11a to 10-11d for mixing pure water and nitrogen gas and for injecting the mixture are disposed above the polishing table 10-1. To each of the mixing and injecting nozzles 10-11a to 10-11d, nitrogen gas pressure of which is adjusted by a regulator 16 is supplied from a nitrogen gas supply source 14 through an air operator valve 18 and pure water pressure of which is adjusted by a regulator 17 is supplied from a pure water supply source 15 through an air operator valve 19.

Regarding the mixed gas and liquid, by altering parameters such as pressure and temperature of the liquid and/or gas and nozzle configuration by means of the injecting nozzle, the liquid to be supplied is changed by the nozzle injection to \mathring{1} fine liquid droplets, \mathring{2} fine solidified particles or \mathring{3} vaporized gas droplets (here, \mathring{1}, \mathring{2} and \mathring{3} are referred to as “fog” or “atomize”), and the mixture of liquid based component and gas component is injected toward the polishing surface of the polishing table 10-1 with predetermined orientation.

When the polishing surface 10-1a is reproduced (dressed) by the relative movement between the polishing surface 10-1a and the dresser 10-10 obtained by sliding them, the mixture fluid comprised of pure water and nitrogen gas is injected toward the polishing surface 10-1a from the mixture injecting nozzles 10-11a to 10-11d, thereby cleaning the polishing surface. The pressure of the nitrogen gas and the pressure of the pure water can be set independently. In the illustrated embodiment, although both the pure water line and the nitrogen gas line include manually driven regulators, these line may include regulators capable of changing set pressure on the basis of an external signal. As a result of the cleaning of the polishing surface 10-1a by using the above-mentioned cleaning mechanism, it was found that, by effecting the cleaning for 5 to 20 seconds, slurry and polished residual matters remaining on the polishing surface after the first and second polishing processes can be removed. Incidentally, although not shown, a cleaning mechanism having the same construction as the cleaning mechanism shown in FIG. 4 is provided to clean the polishing surface 11-1a of the polishing device 11.

In the above-mentioned description, an example that the atomizer and the mechanical dressing are effected simultaneously was explained. However, the atomizer, mechanical dressing, water polishing and water jet may be effected independently or effected with appropriate combination thereof. The mechanical dressing used here is generally is effected by using a diamond dresser designed so that a strip-shaped protruded portion to which diamond particles are electrically adhered is provided along a circumferential area on an under surface of the disk-shaped dresser 10-10 shown in FIG. 4. When the mechanical dressing is effected, both the setting and the cleaning of the polishing surface can be achieved. Other than the diamond dresser, a dresser designed to include a nylon brush can be used.

The water polishing means that, in place of the slurry supplied from the polishing liquid supply nozzle 10-6, pure water is used, and the polishing is effected under the supply of pure water while contacting the semiconductor substrate W with the polishing surface 10-1a as shown in FIG. 3. When the water polishing is performed, the pressing force of the top ring 10-2 is made smaller in comparison with the first and second polishing processes. By performing the water polishing, the polishing liquid used in the first and second polishing processes and remaining on the polishing surface is replaced by the pure water, thereby cleaning the polishing surface 10-1a.

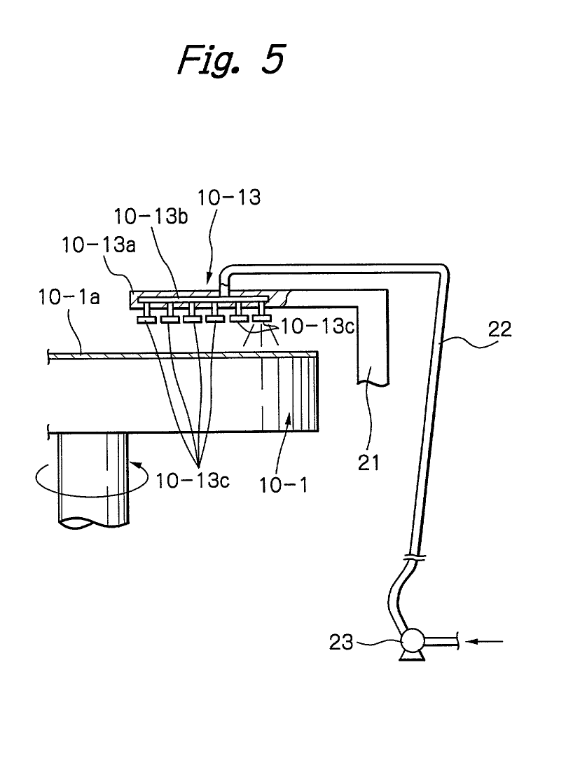

FIG. 5 is a view showing a construction of a cleaning mechanism for cleaning the polishing surface 10-1a of the polishing table 10-1 by using water jet. As shown, a dressing unit 10-13 is provided, and the dressing unit 10-13 includes a plurality (six in the illustrated embodiment) of water jet nozzles 10-13c disposed equidistantly along a radial direction above the polishing surface 10-1a of the polishing table 10-1. Each water jet nozzle 10-13c is secured to a water jet nozzle arm 10-13a having flow paths 10-13b therein.

The pure water pressurized by a pump 23 is supplied to the water jet nozzles 10-13c through a tube 22, and the water jets are injected from the water jet nozzles 10-13c toward the polishing surface 10-1a. Water pressure of the water jet nozzle arm 10-13a is adjusted by a control portion (not shown) for the pump 23 to be maintained to predetermined pressure. Further, the water jet nozzle arm 10-13a has the same construction so that injecting pressures and injecting speeds of water jet from the respective nozzles becomes substantially the same as each other. The pressure of the water jet can be maintained within a predetermined pressure range from 5 to 30 kg/cm² by controlling the pump 23.

Table 1 shows a relationship between a flow of first to third polishing processes and kind of abrasive grain/slurry, top ring pressing force and top ring revolution number used in the polishing processes. As shown in the Table 1, in the first polishing process, silica and copper polishing slurry are used as abrasive grain and slurry, and the top ring pressing force is set to 400 g/cm² and the top ring revolution number (number of revolutions of the top ring) is set to 70 rpm. In the next second polishing process, silica and copper polishing slurry are used as abrasive grain and slurry, and the top ring pressing force is set to 200 g/cm² and the top ring revolution number is set to 70 rpm. It is ascertained whether the copper plating film layer 106 and the feed seed layer 107 are removed or not, by using the end point measurement.

After it was ascertained that the copper plating film layer 106 and the feed seed layer 107 are polished and removed by the end point measurement, the slurry used in the first and second polishing processes and remaining on the polishing surface 10-1a is cleaned and removed by the water polishing or the water jet or the atomizer or the dresser, and then the third polishing process is started. In the third polishing process, silica and Ta polishing slurry are used as abrasive grain and slurry, and the top ring pressing force is set to 200 g/cm² and the top ring revolution number is set to 50 rpm.

It is desirable that the abrasive grain used in the slurry for polishing the barrier layer 105 in the third polishing process is the same as the abrasive grain in the polishing for polishing the copper plating film layer 106 and the feed seed layer 107 in the first and second polishing processes. Further, pH of reagent (for example, oxidizing agent) added to the polishing liquid or slurry in the respective polishing processes is offset toward either acidic side or alkaline side in each polishing process. By using such polishing liquid, the residual matters remaining on the cloth constituting the polishing surface 10-1a in the first and second polishing processes is prevented from reacting to the polishing liquid used in the third polishing process to form any compound.

As a result of tests, it was found, when the silica used in both polishing processes are in the alkaline side and when the silica is in the acidic side, both cases lead to good results. In the film thickness end point detection in the third polishing process, since the film thickness is small, the film thickness measuring device of optical type is used to detect the remainder of the barrier layer 105, and a detection signal is sent to the control portion 20. Incidentally, in the polishing using fixed abrasive grain (abrasive grain dispersed and fixed in binding agent), the slurry is not used as the polishing liquid, but reagent liquid or pure water is supplied to effect the polishing.

In this case, it is preferable that the polishing liquid used in the first and second polishing processes and the polishing liquid used in the third polishing process are both in the alkaline side or both in the acidic side. The polishing liquids representing pH in the same side with respect to pH 7 are desirable. However, when neutral polishing liquid is used, in each polishing process, combinations of neutral/neutral, neutral/alkaline and neutral/acidic can be considered. The important matter is that the acidic polishing liquid and the alkaline polishing liquid are not used simultaneously on the same polishing table.

Incidentally, the abrasive grain used in the first and second polishing processes and the abrasive grain used in the third polishing process do not arise any problem even if particle diameters thereof are different from each other. Further, while an example that the slurry (liquid in which abrasive grain is suspended) is used as the polishing liquid was explained, the polishing liquid is not limited to the slurry. For example, in the third polishing process, the polishing can be effected only by using reagent liquid not including abrasive grain, and, in this case, there is a problem regarding only pH of the polishing liquid used in the first and second polishing processes and pH of the polishing liquid used in the third polishing process. That is to say, in the series of polishing processes, the polishing liquids should be standardized to the acidic side or the alkaline side.

Further, although not shown, the film thickness measuring devices 10-4, 11-4 disposed in the vicinity of the polishing table 10-1 of the polishing device 10 and the polishing table 11-1 of the polishing device 11 are constituted by film thickness measuring devices having image processing devices, so that the film thickness measured by each film thickness measuring device is stored as working record of the semiconductor substrate W and/or judgement is effected whether or not the polished semiconductor substrate W can be transferred to the next process. Further, if a predetermined polished amount is not attained after the polishing is finished, the polishing is performed again. Further, if the excessive amount is polished for any abnormal reason, the apparatus is stopped not to perform the next polishing, thereby preventing the number of poor parts from being increased.

As mentioned above, since the first to third polishing processes can be carried out on the single polishing table 10-1 or 11-1, the number of polishing tables can be reduced, thereby making the entire apparatus more compact and enhancing through-put of the substrate polishing.

After the polishing is finished, the semiconductor substrate W is returned to the pusher 10-5 or 11-5 by the top ring 10-2 or 11-2, and then, the semiconductor substrate W is picked up by the second robot 7 to bring it into the first cleaning machine 8 or 9, and primary cleaning is effected. In this case, reagent liquid may be injected onto the front and rear surfaces of the semiconductor substrate W rested on the pusher 10-5 or 11-5 to remove the particles and/or to treat such surfaces to a condition that the particles are hard to be adhered to such surfaces.

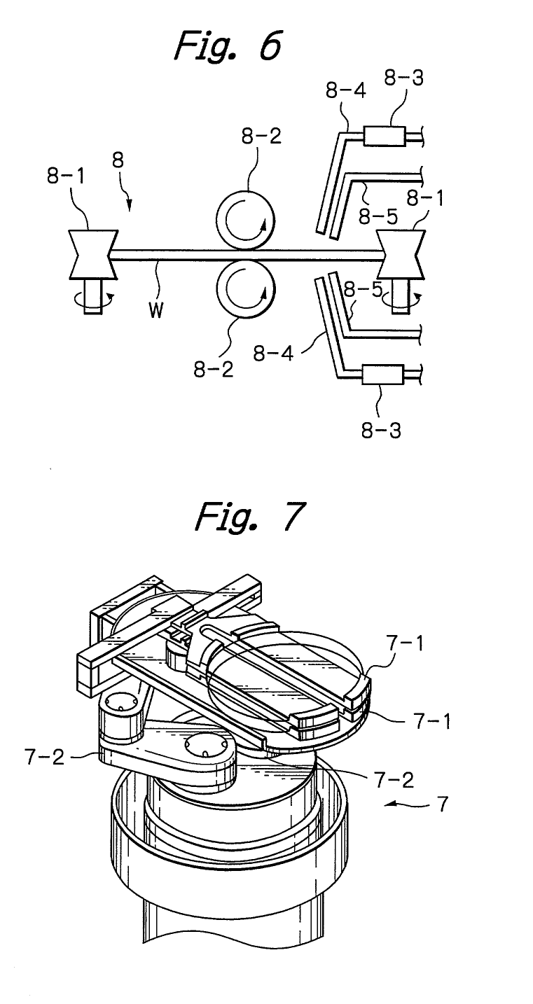

In the primary cleaning by using the first cleaning machine 8 or 9, the front and rear surfaces of the semiconductor substrate W is subjected to scrub cleaning. FIG. 6 shows a construction of the first cleaning machine 8. As shown, in the first cleaning machine 8, the semiconductor substrate W is pinched by a plurality of substrate rotating rollers 8-1 to rotate in a horizontal plane. Rotating PVA sponge rolls 8-2 are provided so that they can be urged against the front and rear surfaces of the semiconductor substrate W. Further, cation water nozzles 8-4 having ultrasonic oscillators 8-3 and DHF nozzles 8-5 are disposed above and below the semiconductor substrate W. In order to remove the particles, pure water, surface-active agent, chelate agent and/or pH adjusting agent are supplied onto the surfaces of the semiconductor substrate W, the scrub cleaning is effected by using the PVA sponge rolls 8-2. Strong reagent liquid such as DHF is sprayed onto the rear surface of the semiconductor substrate W to effect of etching of diffused copper, or, when there is no diffusion, the rear surface of the semiconductor substrate is subjected to the scrub cleaning by using the same reagent liquid as that used regarding the front surface. Incidentally, the first cleaning machine 9 has the same construction as the first cleaning machine 8.

After the cleaning by using the first cleaning machine 8 or 9, the semiconductor substrate W is picked up by the second robot 7, and then, the substrate is transferred to the reverse rotation machine 5 or 6, where the semiconductor substrate W is turned over. The semiconductor substrate is picked up from the reverse rotation machine 5 or 6 by the first robot 2, and the semiconductor substrate is sent to the second cleaning machine 3 or 4, where secondary cleaning is effected. Although not shown, the second cleaning machine 3 or 4 has the same construction as the first cleaning machines 8, 9. Further, pure water, surface-active agent, chelate agent and/or pH adjusting agent may be supplied and the surface may be cleaned by pencil sponge. Thereafter, spin drying is performed and then the semiconductor substrate W is picked up by the first robot 2.

When the film thickness is measured by the film thickness measuring device 10-4 or 11-4 disposed in the vicinity of the polishing table 10-1 or 11-1, the first robot 2 returns the semiconductor substrate W onto the cassette rested on the unload port of the load/unload portion 1. When the multi-layer film measurement is performed, since the measurement must be performed under a dried condition, the film thickness is measured by the dried condition film thickness measuring device 13. Where, the measured film thickness is stored as working record of the semiconductor substrate W and/or judgement is effected whether or not the polished semiconductor substrate can be transferred to the next process.

FIG. 7 is a perspective view of the second robot 7. As shown, the second robot 7 has two upper and lower hands 7-1, and the hands 7-1 are attached to distal ends of respective arms 7-2 so that they can be turned. The semiconductor substrate W is dipped up by the hands 7-1 (semiconductor substrate W is dropped down), so that the semiconductor substrate can be transferred to a desired position.

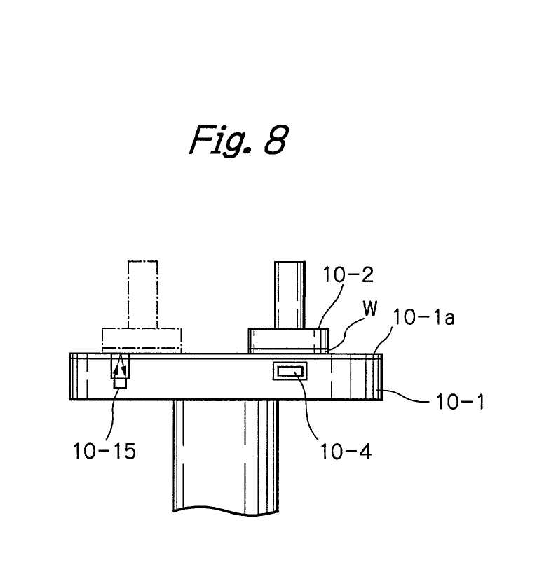

FIG. 8 is a view showing the construction of the film thickness measuring device provided on the polishing device 10 and adapted to measure the film thickness of the semiconductor substrate W being polished. As shown, a film thickness measuring device 10-14 of eddy current type and a film thickness measuring device 10-15 of optical type are provided within the polishing table 10-1 and serve to measure the film thickness of the polished surface of the semiconductor substrate held by the top ring 10-2 and being polished.

In the film thickness measuring device 10-14 of eddy current type, eddy current is generated in conductive films (copper plating film layer 106 and feed seed layer 107) of the semiconductor substrate W by applying high frequency electrical current to a sensor coil, and, since the eddy current is changed in accordance with the film thickness, by monitoring combined impedance with a sensor circuit, the film thickness is measured.

On the other hand, the film thickness measuring device 10-15 of optical type has a light emitting element and a light receiving element and is designed so that light from the light emitting element is illuminated onto the surface to be polished of the semiconductor substrate W and light reflected from the surface to be polished is received by the light receiving element. As the conductive film (Cu film) of the semiconductor substrate W reached a predetermined film thickness, a part of the light illuminated from the light emitting element onto the surface to be polished is permeated through the conductive film, with the result that there exist two light, i.e., reflected light reflected from the oxidation film (SiO₂) underlying the conductive film and reflected light reflected from the surface of the conductive film. By receiving such two lights by means of the light receiving element and by processing such lights, the film thickness is measured.

Next, another embodiment of the present invention will be explained. Incidentally, in an embodiment which will be described hereinbelow, while an example that a Ti film, a TiN film and a W film successively laminated on an oxidation film of a silicon substrate is explained, of course, the films polished by a substrate polishing method according to the present invention are not limited to such films.

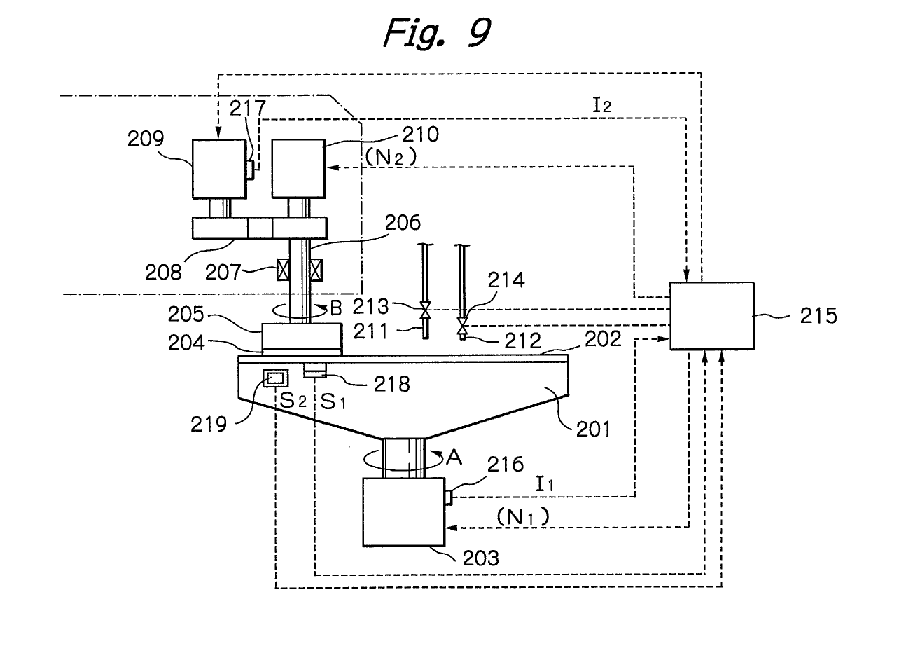

FIG. 9 is a view showing a construction of a substrate polishing apparatus carrying out the substrate polishing method according to the present invention. In FIG. 9, a polishing cloth 202 is adhered to an upper surface of a polishing table 201 which is in turn rotated by a polishing table driving motor 203 in a direction shown by the arrow A. A top ring 205 for holding a substrate 204 is rotated while pressing the substrate against the upper surface of the polishing cloth 202, and this top ring is attached to a rotary shaft 206 and is rotatably supported via a bearing 207.The rotary shaft 206 is rotated by a top ring driving motor 209 via a gearing mechanism 208.

An urging cylinder 210 serves to urge the top ring 205 holding the substrate 204 against the upper surface of the polishing cloth 202 of the polishing table 201. Further, a slurry supply nozzle 211 for supplying slurry to the upper surface of the polishing cloth 202 is connected to a slurry supply source (not shown) via an open/close valve 213. A water supply nozzle 212 for supplying water to the upper surface of the polishing cloth 202 is connected to a water supply source (not shown) via an open/close valve 214. A control device 215 serves to receive a current detection signal I1 of the polishing table driving motor 203 detected by a current sensor 216, a current detection signal I2 of the top ring driving motor 209 detected by a current sensor 217, a film thickness detection signal S1 detected by an optical film thickness sensor 218, and a film thickness detection signal S2 detected by a film thickness sensor 219 of eddy current type.

Further, the control device 215 serves to control the urging cylinder 210, thereby controlling the pressing force (substrate pressing load) applied to the top ring 205 and to control the polishing table driving motor 203 and the top ring driving motor 209, thereby controlling a rotational speed N1 of the polishing table 201 and a rotational speed N2 of the top ring 205.

In the substrate polishing apparatus having the above-mentioned construction, the substrate polishing method according to the present invention serves to perform the polishing through three or more polishing processes in which at least one of the substrate pressing load for pressing the substrate 204 against the upper surface of the polishing cloth 202 of the polishing table 201, numbers of revolutions of the polishing table 201 and the top ring 205, and polishing liquid (slurry, water, mixture of water and inert gas or the like) is changed.

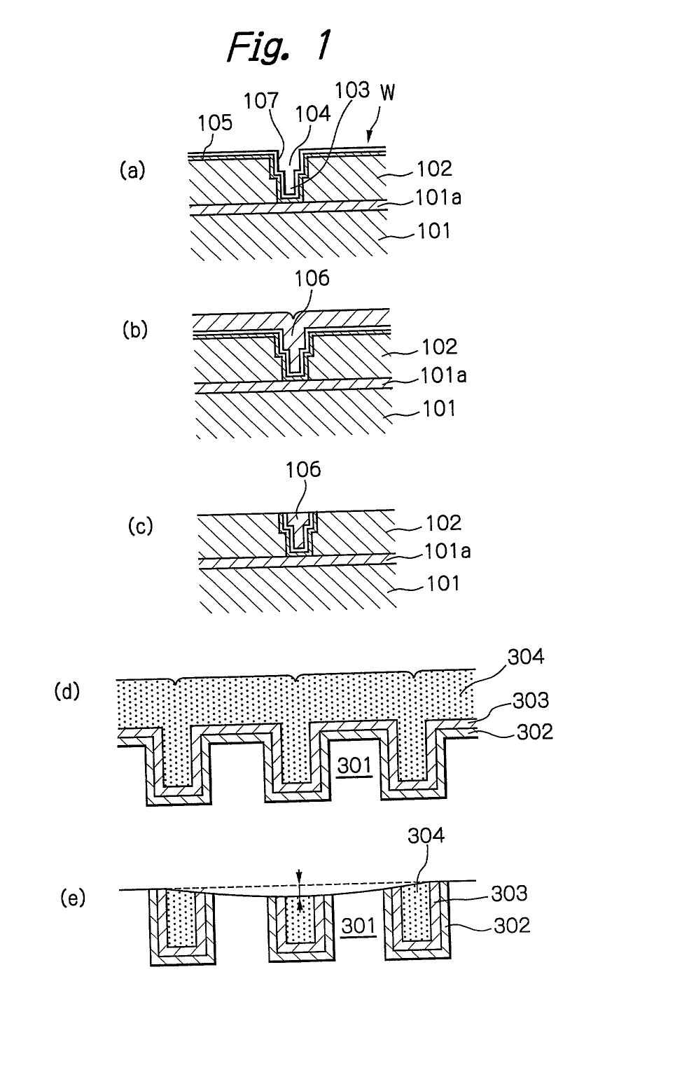

Table 2 shows a concrete relationship between the polishing processes and the polishing conditions. Here, as shown in FIGS. 1(d) and 1(e), the substrate on which an oxidation film 301, a Ti film 302, a TiN film 303 and a W film 304 was successively laminated is polished, and the polishing is performed through steps 1 to 6 (polishing processes). Further, the numbers of revolutions of the polishing table and the top ring 205 are set to be constant, and the polishing conditions in the respective polishing processes are selected as follows.

In the step 1, slurry is used as the polishing liquid and the substrate pressing load is set to 500 kgf/cm², and, in the the step 2, slurry is used as the polishing liquid and the substrate pressing load is set to 400 kgf/cm², and, in the the step 3, slurry is used as the polishing liquid and the substrate pressing load is set to 200 kgf/cm², and, in the the step 4, water is used as the polishing liquid and the substrate pressing load is set to 50 kgf/cm², and, in the the step 5, slurry is used as the polishing liquid and the substrate pressing load is set to 100 kgf/cm², and, in the the step 6, water is used as the polishing liquid and the substrate pressing load is set to 50 kgf/cm². In the carious steps, the same type slurry is used, and multi-polishing is effected on the same polishing table while changing only the load.

In the substrate polishing apparatus shown in FIG. 9, execution of the steps 1 to 6 (polishing processes) will be explained. By the control of the control device 215, the polishing table 201 and the top ring 205 are rotated with predetermined number of revolutions (rotational speeds) and the pressing force, i.e., substrate pressing load applied to the top ring 205 is set to 500 kgf/cm² by controlling the urging cylinder 210, and the polishing is effected for 10 seconds (polishing of step 1). Then, the substrate pressing load is changed to 400 kgf/cm², and the polishing is effected for 30 seconds (polishing of step 2). Then, the substrate pressing load is changed to 200 kgf/cm², and the polishing is effected for 60 seconds (polishing of step 3). In these steps 1 to 3, the control device 215 opens the open/close valve 213 (in this case, the open/close valve 214 is closed), with the result that the slurry is supplied onto the upper surface of the polishing cloth 202 through the slurry supply nozzle 211.

The polishing process regarding the step 3 is finished by detection (end point detection) of the TiN film 303. When the W film is polished and removed and the TiN film 303 abuts against the polishing cloth 202, since the friction force is changed, the electrical current of the polishing table driving motor 203 for driving the polishing table 201 is also changed. The control device 215 can detect the TiN film 303 (end point detection) on the basis of change in current detection signal I1 of the polishing table driving motor 203 detected by the current sensor 216. After the TiN film 303 is detected, the open/close valve 214 is opened (in this case, the open/close valve 213 is closed) to supply the water onto the upper surface of the polishing cloth 202 through the water supply nozzle 212, and, at the same time, the substrate pressing load is changed to 50 kgf/cm² by controlling the pressing force of the urging cylinder 210, and the water polishing is effected (polishing of step 4).

The water polishing has a function for cooling high temperature portions on the polishing surface of the polishing cloth 202 and slurry and the polished surface of the substrate 204 heated by the slurry polishing with great substrate pressing load in the steps 1 to 3, thereby suppressing polishing (erosion) of the W film 304 to keep the uniformity of the polished surface of the substrate 204.

After the water polishing is performed for a predetermined time period, the open/close valve 213 is opened (in this case, the open/close valve 214 is closed) to supply the slurry onto the upper surface of the polishing cloth 202 through the slurry supply nozzle 211, and, at the same time, the substrate pressing load is changed to 100 kgf/cm² by controlling the pressing force of the urging cylinder 210, and the slurry polishing is effected (polishing of step 5). By such slurry polishing, the TiN film 303 and the Ti film 302 are polished and removed. The completion of the slurry polishing in the step 5 is determined by the removal of the Ti film 302, i.e., detection (end point detection) of the oxidation film 301. Similar to the above, the detection of the oxidation film 301 can be effected by the control device 215 on the basis of change in the current detection signal I1 of the polishing table driving motor 203 detected by the current sensor 216.

After the polishing in the step 5 is finished, the control device 215 opens the open/close valve 214 (in this case, the open/close valve 213 is closed) to supply the water onto the upper surface of the polishing cloth 202 through the water supply nozzle 212, and, at the same time, the substrate pressing load is changed to 50 kgf/cm² by controlling the pressing force of the urging cylinder 210, and the water polishing is effected for a predetermined time period (polishing of step 6).

As mentioned above, by effecting the slurry polishing in the steps 1 to 3 while changing the substrate pressing load (500˜200 kgf/cm²), the uniformity of the polished surface of the substrate 204 is improved, in comparison with the conventional polishing with the same load. Table 3 shows an example of uniformity of substrate polishing achieved when the conventional polishing is effected with the same substrate pressing load, and Table 4 shows an example of uniformity of substrate polishing (polishing according to the present invention) achieved when the polishing is effected while changing the substrate pressing load as in the steps 1 to 3. As apparent from the Table 3 and the Table 4, it can be seen that the uniformity of the polished surface is improved by the polishing of the present invention more than the conventional polishing. Further, while oxide erosion was 40 to 50 nm in the conventional case, in the present invention, it can be suppressed to 20 nm or less.

As mentioned above, by effecting the slurry polishing to remove the W film 304 while changing the substrate pressing load (500˜200 kgf/cm²) in the steps 1 to 3 and then by effecting the water polishing in the step 4 and then by effecting the slurry polishing with smaller load to remove the TiN film 303 and the Ti film 302 and, lastly, by effecting the water polishing in the step 6, the oxide erosion can be improved, thereby enhancing the uniformity of the polished surface of the substrate 204. Further, since the plural polishing processes can be performed on the same table, there is no loss time for changing the table, with the result that the through-put of processing can be enhanced and space can be saved.

Atomizer polishing in which the polishing is effected while supplying mixture of water and inert gas such as nitrogen onto the upper surface of the polishing cloth 202 through the water supply nozzle 212 may be added to the water polishing using the water as the polishing liquid in the steps 4 and 6. Further, although not shown, independently from the water supply nozzle 212, a mixture supply nozzle may be additionally provided to supply the mixture of water and inert gas onto the upper surface of the polishing cloth 202 through the mixture supply nozzle under the control of the control device 215.

Further, in the above description, while an example that the finishing point of the polishing process, i.e., end point is detected on the basis of the change in the current detection signal I1 of the polishing table driving motor 203 detected by the current sensor 216 was explained, in place of this, the end point may be detected on the basis of the change in the current detection signal I2 of the top ring driving motor 209 detected by the current sensor 217. That is to say, when the film thickness of the polished surface of the substrate 204 is changed, since the friction force between the polished surface of the substrate 204 and the polishing surface of the polishing cloth 202 is changed, and, thus, the current I2 of the top ring driving motor 209 for driving the top ring 205 is also changed, the end point can be detected on the basis of the change in current. However, if the holding force (for example, vacuum absorbing force) of the top ring 205 for holding the substrate 204 is weak so that the substrate 204 is rotated with respect to the top ring 205, the end point cannot sometimes be detected correctly.

Further, in the above description, while an example that the the end point is detected on the basis of the change in the current detection signal I1 of the polishing table driving motor 203 or the change in the current I2 of the top ring driving motor 209 was explained, when the friction force is changed, since vibration or sound of the polishing table and/or the top ring 205 is also changed, by monitoring such vibration or sound, the end point may be detected on the basis of the change in such vibration or sound.

Further, an optical film thickness sensor 218 or a film thickness sensor 219 of eddy current type may be provided in the polishing table 201 so that the film thickness is detected whenever the optical film thickness sensor 218 or the film thickness sensor 219 of eddy current type is passed through the under surface of the polished surface of the substrate 204 by the rotation of the polishing table 201, and detection output is sent to the control device 215 which in turn detects the end point on the basis of the film thickness detection output.

Incidentally, the optical film thickness sensor 218 has a light emitting element and a light receiving element and is designed so that light from the light emitting element is illuminated onto the polished surface of the substrate 204 and light reflected from the polished surface is received by the light receiving element and the film thickness is measured on the basis of the received light. In this case, the light emitted from the light emitting element may be a laser beam or light from a light emitting diode (LED). On the other hand, the film thickness sensor 219 of eddy current type has a sensor coil and is designed so that eddy current is generated in the conductive film of the polished surface of the substrate 204 by applying high frequency electrical current to the sensor coil and, since the eddy current is changed in accordance with the film thickness, by monitoring composite impedance with a sensor circuit, the film thickness is measured.

Incidentally, in the above description, while an example that the substrate having the oxidation film 301 on which the Ti film 303, TiN film 302 and W film 304 were successively laminated is polished was explained, the substrate polishing method according to the present invention is not limited to such an example, but, for example, can be applied to polishing of a substrate having an oxidation film on which a barrier layer and a copper (Cu) film are formed.

Further, in the above description, while an example that the polishing is performed while changing the substrate pressing load and/or the polishing liquid (slurry, water, mixture of water and inert gas) was explained, other than this, for each polishing process, the number of revolutions of the polishing table and/or the number of revolutions of the top ring may be changed.

The present description and attached drawings depict embodiments wherein a top ring as well as a polishing table is independently rotated, but the present invention is not limited to only such embodiments, and in case that a polishing surface moves reciprocally or in orbital motions, it is possible to change relative speed between the top ring and the polishing table by changing the transfer speed of the polishing surface.

Further, in the above description, while an example that the polishing cloth 202 is adhered to the upper surface of the polishing table 201 was explained, in the substrate polishing method according to the present invention, a grinding stone plate may be attached to the upper surface of the polishing table 201. Incidentally, in this case, generally, since water (rather than the slurry) is used as the polishing liquid, in this case, the polishing liquid (water) is not changed between the polishing processes.

As mentioned above, according to the present invention, the following excellent effect can be achieved.

Since the substrate polishing is effected on the same polishing table, the number of polishing tables can be reduced, and at the same time, the through-put (processing amount per unit time) for the substrate polishing can be enhanced.

According to the present invention, by effecting the polishing through three or more polishing processes in which at least one of the substrate pressing load, the relative speed between the polishing table and the substrate and the polishing liquid is changed, i.e., the polishing conditions are changed (for example, the substrate pressing load is changed), the uniformity of the polished surface can be improved in comparison with the prior art.

According to the present invention, since the completion of the polishing process is determined by the detection of the film thickness, for example, after the polishing of a certain film is finished, when the polishing of other film is started, the polishing conditions (for example, polishing liquid, substrate pressing load) can be changed to suit for such polishing.

According to the present invention, by adding the water polishing and/or the atomizer polishing after the last polishing process, since the high temperature portions of polished surface of the substrate and the polishing surface of the polishing table heated in the preceding process can be cooled and at the same time the polishing liquid used in the preceding process can be removed, the erosion of the polished surface of the substrate can be prevented, thereby enhancing the uniformity.

According to the present invention, by polishing the substrate on which the W film was formed through three or more polishing processes, for example, while changing the substrate pressing load, the uniformity of the polished surface can be improved in comparison with the prior art.

TABLE 1

| | Abrasive grain | Top ring | Top ring |
|---|---|---|---|
| | slurry | urging force | revolution number |
| First polishing process | Silica, Cu polishing slurry | 400 g/cm³ | 70 rpm |
| ↓ | | | |
| Second polishing process | Silica, Cu polishing slurry | 200 g/cm² | 70 rpm |
| ↓ | | | |
| End point measurement | | | |
| ↓ | | | |
| Polished surface cleaning | | | |
| ↓ | | | |
| Third polishing process | Silica, Ta polishing slurry | 200 g/cm³ | 50 rpm |

TABLE 2

| Polishing process | Step 1 | Step 2 | Step 3 | Step 4 | Step 5 | Step 6 |
|---|---|---|---|---|---|---|
| Polishing liquid | slurry | slurry | slurry | water | slurry | water |
| Substrate urging | 500 kgf/cm² | 400 kgf/cm² | 200 kgf/cm² | 50 kgf/cm² | 100 kgf/cm² | 50 kgf/cm² |
| load | | | | | | |

TABLE 3

[chemical structure]

TABLE 4

[chemical structure]

What is claimed is:

1. A substrate polishing apparatus comprising:
a polishing table having a polishing surface; and
a top ring for holding a substrate;
wherein a semiconductor substrate held by said top ring is pressed against said polishing surface of said polishing table and a surface to be polished of the semiconductor substrate is polished by a relative movement between the semiconductor substrate and said polishing surface;
the apparatus further comprising:
pressing force changing mechanism for changing an pressing force for pressing the semiconductor substrate;
relative movement speed changing mechanism for changing the speed of relative movement between said top ring and said polishing table; and
control mechanism;
wherein said control mechanism performs plural polishing processes on the same polishing table while changing the pressing force and the relative movement through said pressing force changing mechanism and said relative movement speed mechanism.

2. A substrate polishing apparatus according to claim 1, further comprising film thickness detecting means for detecting a film thickness of the semiconductor substrate, and wherein said control mechanism performs transfer from the preceding polishing process to the next polishing process on the basis of a film thickness detection signal detected by said film thickness detecting means.

3. A substrate polishing apparatus according to claim 1 or 2, further comprising dressing means for dressing said polishing surface of said polishing table or cleaning means for cleaning said polishing surface of said polishing table, and wherein said control mechanism controls said dressing means or said cleaning means between the polishing processes to effect the dressing or the cleaning of said polishing surface of said polishing table.

4. A substrate polishing method in which a semiconductor substrate held by a top ring is pressed against a polishing surface of a polishing table and a surface to be polished of the semiconductor substrate is polished by a relative movement between the semiconductor substrate and said polishing surface, wherein:
the semiconductor substrate is polished on the same polishing table through plural polishing processes while changing an pressing force for pressing the semiconductor substrate and the number of revolutions of said top ring and/or said polishing table.

5. A substrate polishing method according to claim 4, wherein, when said plural polishing processes are performed, the polishing is effected while adding polishing liquid and/or reagent liquid having having pH at the same side as pH 7.

6. A substrate polishing method according to claim 4, wherein, when said plural polishing processes are performed, the polishing is effected by using same abrasive grain.

7. A substrate polishing method in which a semiconductor substrate held by a top ring is pressed against a polishing surface of a polishing table and a surface to be polished of the semiconductor substrate is polished by a relative movement between the semiconductor substrate and said polishing surface,
wherein the polishing is effected on a single polishing table through plural stage polishing processes, and, after one stage polishing process is finished, said polishing surface of said polishing table is cleaned, and then the next stage polishing process is performed.

8. A substrate polishing method in which a substrate held by a top ring is pressed against a polishing surface of a polishing table and a film formed on a surface of the semiconductor substrate is polished to achieve flatness by a relative movement between the semiconductor substrate and said polishing surface,
wherein the polishing is performed through three or more polishing processes in which at least one of a substrate pressing load for pressing the substrate against said polishing surface of said polishing table, a relative speed between said polishing table and the substrate and polishing liquid is changed.

9. A substrate polishing method according to claim 8, wherein completion of at least last polishing process among three or more polishing processes is determined by detection of a thickness of the film.

10. A substrate polishing method according to claim 8, wherein, after at least last polishing process among three or more polishing processes is finished, a water polishing process using water as the polishing liquid is performed.

11. A substrate polishing method according to claim 10, wherein an atomizer polishing process using mixture of water and inert gas as the polishing liquid is added to the water polishing process.

12. A substrate polishing method according to claim 8, wherein the film formed on the substrate surface a film comprised of an oxidation film, a Ti film, a TiN film and a W film successively laminated on the substrate surface.
